(19) United States
(12) Patent Application Publication
(10) Pub. No.: US 2017/0020029 A1
(43) Pub. Date: Jan. 19, 2017

(54) Electronic Apparatus

(71) Applicant: COMPAL BROADBAND NETWORKS INC., Taipei City (TW)

(72) Inventors: Cheng-Shan Lin, Hsinchu County (TW); Chung-Ming Pan, Hsinchu County (TW)

(21) Appl. No.: 15/164,891

(22) Filed: May 26, 2016

Related U.S. Application Data
(60) Provisional application No. 62/193,099, filed on Jul. 16, 2015.

(30) Foreign Application Priority Data
Nov. 26, 2015 (TW) 104218975

(51) Int. Cl. H05K 7/20; H05K 7/18

(52) U.S. Cl. CPC H05K 7/20136; H05K 7/186

(57) ABSTRACT

An electronic apparatus is configured for processing a network communication operation. The electronic apparatus includes a frame and a plurality of electronic modules. The plurality of electronic modules are disposed on the frame and each electronic module is closely surrounded by other electronic modules for forming a pillar-shape wind channel, such that the electronic apparatus is assisted to process a heat dissipation.

### CROSS REFERENCE TO RELATED APPLICATIONS

This application claims the benefit of both U.S. Provisional Application No. 62/193,099, filed on Jul. 16, 2015 and entitled “The structure design of new product”, the contents of which are incorporated herein.

### BACKGROUND OF THE INVENTION

1. Field of the Invention

The present invention relates to an electronic apparatus, and more particularly, to an electronic apparatus having a unique structure for effectively dissipating heat of the electronic apparatus and efficiently reutilizing the internal space of the electronic apparatus.

2. Description of the Prior Art

For the sake of comfortable operations for users and fitting different living/working circumstances, exterior appearances of many electronic apparatuses are designed to approach a simplified structure. Conventionally, some internal electronic elements inside the electronic apparatus, such as circuit boards, antennas, dissipating elements, are configured in a planar layout. However, the planar layout for a vertically configured/arranged electronic apparatus may result in a waste of internal space and a poor design for dissipating heat circulating inside the electronic apparatus.

Under such circumstances, it has become an important issue to provide another layout/design having better internal space utilization and heat dissipation for the vertically configured/arranged electronic apparatus, and to maintain proper functional operation and protection of the electronic apparatus.

### SUMMARY OF THE INVENTION

Therefore, the primary objective of the present invention is to provide an electronic apparatus having a unique structure for effectively dissipating heat of the electronic apparatus and efficiently reutilizing the internal space of the electronic apparatus.

The present invention discloses an electronic apparatus, configured for processing a network communication operation, comprising a frame; and a plurality of electronic modules, disposed on the frame; wherein each electronic module is closely surrounded by other electronic modules to forma column-shape wind channel, such that the electronic apparatus is assisted to process a heat dissipation.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an exploded schematic diagram of an electronic apparatus according to an embodiment of the invention.

FIG. 2 to FIG. 4 illustrate different viewpoint diagrams of an entire electronic apparatus shown in FIG. 1 of the invention.

FIG. 5 and FIG. 6 illustrate different schematic diagrams of electronic apparatuses according to embodiments of the invention.

### DETAILED DESCRIPTION

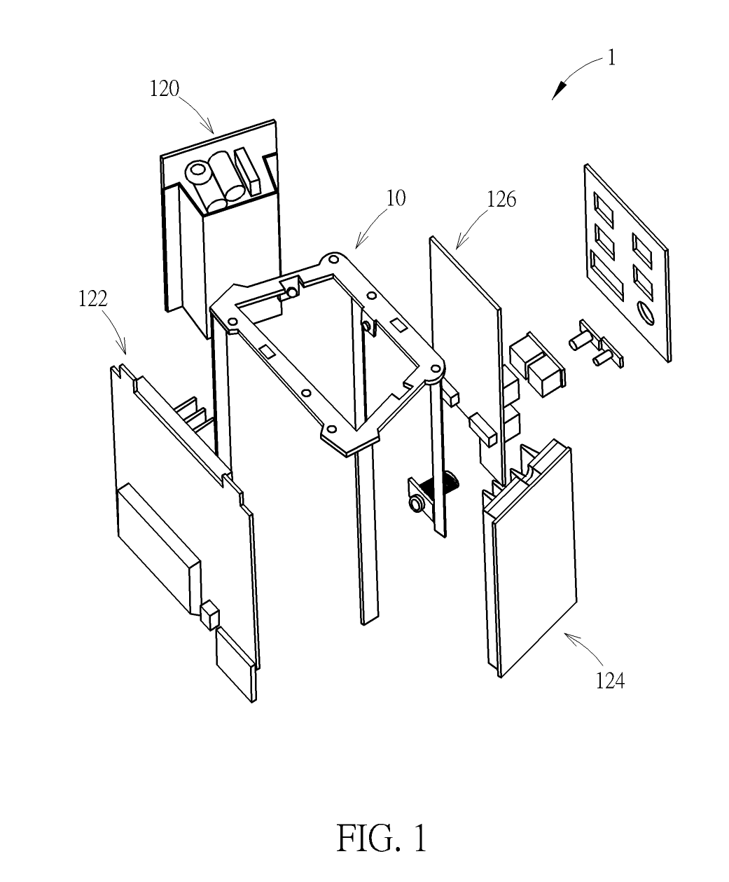

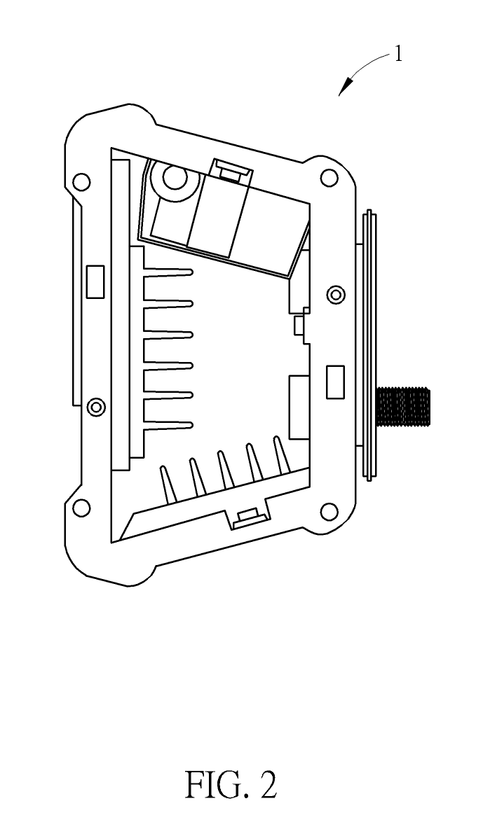

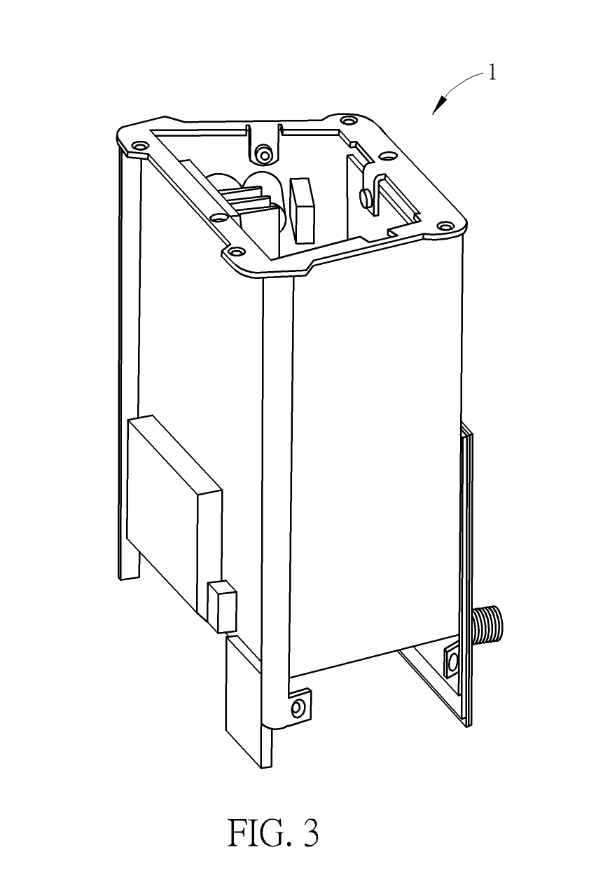

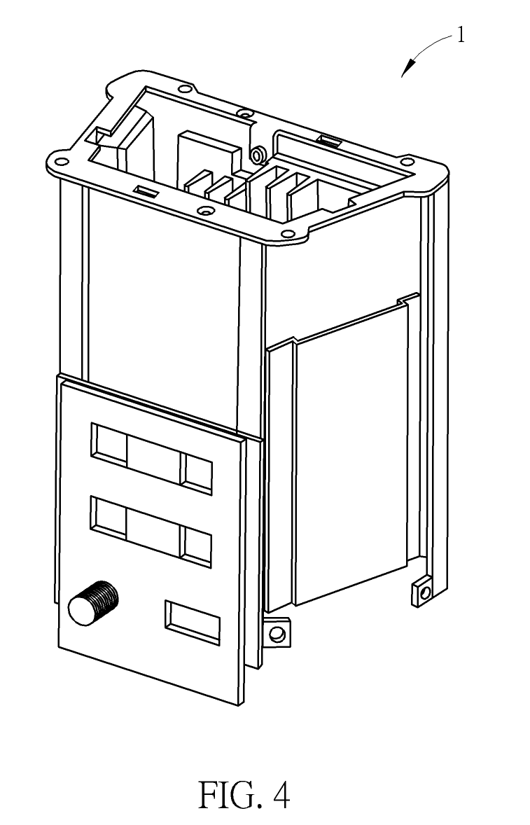

Please refer to FIG. 1 to FIG. 4, wherein FIG. 1 illustrates an exploded schematic diagram of an electronic apparatus 1 according to an embodiment of the invention, and FIG. 2 to FIG. 4 illustrate different viewpoint diagrams of the entire electronic apparatus 1 shown in FIG. 1 of the invention.

As shown in FIG. 1 to FIG. 4, the electronic apparatus 1 of the embodiment comprises a frame 10 and a plurality of electronic elements 120, 122, 124, 126, wherein the electronic modules 120, 122, 124, 126 are sequentially disposed onto the frame 10, and each electronic module is closely surrounded by other electronic modules to forma column-shape wind channel, so as to assist a heat dissipation of the electronic apparatus 1.

Preferably, the frame 10 of the embodiment is an empty brace and comprises a plurality of connecting units, on which a plurality of holes/openings are disposed, such that the connecting units are configured to cooperate different functional composition modules/units. As a whole, the frame 10 is regarded as a quadrilateral shape from a top view and as a pillar structure from a side view. The material of the frame 10 can be the metal material or the nonmetal material with the solid characteristic, which is not limiting the scope of the invention. According to different utilizations and structural designs, those skilled in the art can dispose/arrange at least one connecting module/element on the frame 10 and cooperate with a fixing approach, such as a mechanical pressing, a lock, or a hook, to form the connection relationship of the electronic modules 120, 122, 124, 126 and the plurality of connecting units of the frame 10. Also, the frame 10 is externally covered by a housing to protect and shield the internal composition modules/units, and more decoration or painting can also be added on the housing of the electronic apparatus 1, which is also within the scope of the invention.

Under such circumstances, the electronic modules 120, 122, 124, 126 are disposed to surround edges of the frame 10, and each electronic module is closely surrounded by other electronic modules to form a trapezoid structure (from a top view) which is hollow inside for forming the column-shape wind channel. In other words, from the side view, at least one electronic module is disposed onto each plane of the frame 10; from the top view, most top areas of the frame 10 are hollow, i.e. a user can directly see the bottom of the frame 10 from the top of the frame 10, or can see the configuration/disposition of each electronic module inside the electronic apparatus 1.

Preferably, the plurality of electronic modules 120, 122, 124, 126 of the embodiment are printed circuit boards, and each is configured to process different operations, so as to have the electronic apparatus 1 process a wireless/wired communication operation. For example, the electronic apparatus 1 is a cable modem with the wireless access function, and the electronic modules 120, 122, 124, 126 can arrange at least one o more of a processing module, a memory module, a cable data processing module, a wireless signal communication module, a wireless signal processing module and an input-output control module.

Since the printed circuit board comprises a plurality of composition modules/units which are not uniformly disposed on a plane (i.e. non-planar composition modules/units), the conventional layout of the plurality of printed circuit board would cost a waste an internal utilization space of the electronic apparatus 1. Accordingly, the embodiment of the invention adaptively modifies the structure of the electronic apparatus 1 to be the trapezoid structure comprising the hollow pillar structure, and the printed circuit boards of the embodiment are disposed to surround the frame 10 for increasing an available utilization area of each electronic module, such that the plurality of non-planar composition modules/units on the printed circuit boards can be disposed inside the hollow pillar structure to have the non-planar composition modules/units interleaving inside the pillar structure without overlapping or collision.

Furthermore, the embodiment of the invention further comprises a fan (not shown in the figure) to be disposed at a base of the column-shape wind channel, such that a rotation vane of the fan is configured to generate an upward conduction air, which flows from the bottom to the top (i.e. inhaling an external cold air via the fan) or from the top to the bottom (i.e. expelling an internal hot air via the fan), so as to assist the heat dissipation of the electronic apparatus 1. In other words, the column-shape wind channel of the embodiment not only increases the available utilization area of the plurality of electronic modules, but also increases the heat dissipation rate of the electronic modules, which largely improves the operational efficiency as well as the protection of the electronic apparatus 1.

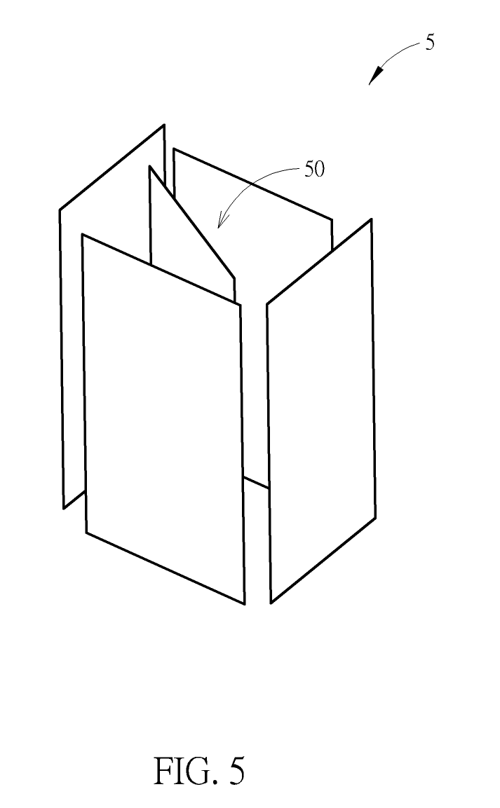

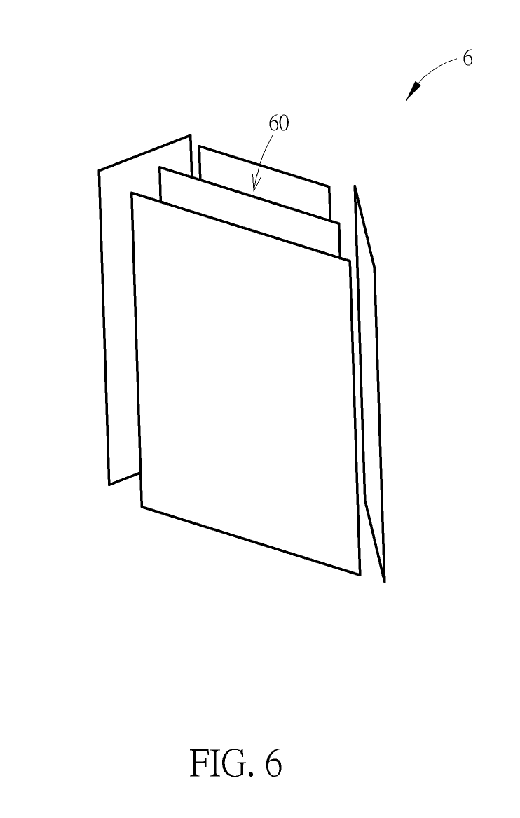

Noticeably, the embodiment of the invention has the electronic modules 120, 122, 124, 126 to be surrounded at the edges of the frame 10, and in another embodiment, the electronic apparatus 1 can further comprise other electronic module(s), such that those skilled in the art can adaptively modify/change the structural design to add other configuration holes and/or fixing locks, so as to fix other electronic module(s) inside the column-shape wind channel. For example, as shown in FIG. 5, the electronic apparatus 5 further comprises another electronic module 50 to be disposed at a diagonal line of the trapezoid structure, i.e. the electronic module 50 divides the column-shape wind channel into two triangle-shape wind channels. Alternatively, as shown in FIG. 6, the electronic apparatus 6 further comprises another electronic module 60 to be disposed at a midline connecting two legs of the trapezoid structure, i.e. the electronic module 60 is configured to approximately parallel two bases of the trapezoid structure, so as to divide the column-shape wind channel into two smaller column-shape wind channels (or two smaller trapezoid-shape wind channels).

Certainly, considering to utilize a larger number of the electronic modules, if there are more electronic modules left after the user has disposed the most electronic modules around the frame 10, those skilled in the art can adaptively arrange the left electronic modules inside the column-shape wind channel in parallel with the bottom plane of the electronic apparatus, i.e. forming a multiple layer structure in the column-shape wind channel, which is also within the scope of the invention. In addition, by utilizing the column-shape wind channel, those skilled in the art can also adaptively operate the fan with different operations for inhaling the external air or expelling the internal air, and more heat-dissipation holes can be correspondingly disposed on the housing with different positions, which is also within the scope of the invention.

In summary, the embodiments of the invention provide a unique structural design of the electronic apparatus. By circularly surrounding a plurality of electronic modules at the edges of the frame of the electronic apparatus, more available utilization area of the electronic apparatus is anticipated to have the electronic apparatus approach a thinner and smaller structure. Besides, due to the advantage of surrounding the plurality of electronic modules, the heat generated by the plurality of electronic modules can be easily collected and be efficiently dissipated, so as to significantly improve the operational efficiency and protection of the electronic apparatus.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic apparatus, configured for processing a network communication operation, comprising:
a frame; and
a plurality of electronic modules, disposed on the frame;
wherein each electronic module is closely surrounded by other electronic modules to form a column-shape wind channel, such that the electronic apparatus is assisted to process a heat dissipation.

2. The electronic apparatus of claim 1, wherein the plurality of electronic apparatuses are closely surrounded to each other to form a trapezoid structure which is hollow inside for forming the column-shape wind channel.

3. The electronic apparatus of claim 2, wherein the trapezoid structure increases an available utilization area of each electronic module, and the plurality of electronic modules are a plurality of printed circuit boards.

4. The electronic apparatus of claim 2, further comprising another electronic module to be disposed at a diagonal line of the trapezoid structure.

5. The electronic apparatus of claim 2, further comprising another electronic module to be disposed at a midline connecting two legs of the trapezoid structure.

6. The electronic apparatus of claim 1, further comprising a fan to be disposed at a base of the column-shape wind channel, such that the fan is configured to generate an upward conduction air to assist the heat dissipation of the electronic apparatus.
